(19) United States
(12) Patent Application Publication
(10) Pub. No.: US 2005/0111170 A1
(43) Pub. Date: May 26, 2005

(54) Hand-held devices

(76) Inventor: Yin-Hsiang Thy, Yonghe City (TW)

Correspondence Address: Lawrence D. Eisen, Esq.;SHAWPITTMAN LLP, 1650 Tysons Boulevard, McLean, VA, 22102, US

(21) Appl. No.: 10/989,001

(22) Filed: Nov. 16, 2004

(30) Foreign Application Priority Data
Nov. 25, 2003 (CN) 200320123 709.8

(51) Int. Cl. G06F 1/16; H05K 5/00

(52) U.S. Cl. 361/679

(57) ABSTRACT

A portable electronic device includes a main body for performing a function of the portable electronic device, a display unit removable or separable from the main body for displaying a result of the function performed by the main body, and a transmission line for electrically connecting the main body and the display unit such that the display unit can be separated from the main body without disconnecting the electrical connection between the display unit and the main body.

### BACKGROUND

I. Field of the Invention

The present invention relates generally to a portable electronic device and, more particularly, relates to a hand-held communication device.

II. Background of the Invention

Portable electronic devices such as cell phones, digital cameras, personal digital assistants (“PDA”s) or the like are getting more and more popular today. Such portable electronic devices typically include display screens to provide real-time image or information display during operation. In general, a display screen is immobile with respect to a main body of a portable device and is not allowed to separate from the main body during operation.

FIG. 1 is a perspective view of a conventional portable electronic device 1. Referring to FIG. 1, portable electronic device 1 includes a keypad 2, a camera lens 3 and a display screen 4. Display screen 4 is immobile with respect to keypad 2 or camera lens 3. When in use, a user of portable electronic device 1 typically keeps display screen 4 in sight in order to view in real time an image or picture taken by camera lens 3. In operation, display screen 4 and camera lens 3 are held at substantially the same elevation or position. In some situations, however, it may be desirable for a user to take a picture through camera lens 3 at a first elevation while viewing its image at display screen 4 at a second elevation different from the first elevation. Moreover, it may be desirable to replace a component such as display screen 4 with another one. It is therefore desirable to have a portable electronic device that allows a display screen to mechanically separate from a camera lens during operation and provides the flexibility of component replacement.

### BRIEF SUMMARY OF THE INVENTION

The present invention is directed to an apparatus and a method that obviate one or more problems resulting from the limitations and disadvantages of the prior art.

In accordance with an embodiment of the present invention, there is provided a portable electronic device that comprises a main body for performing a function of the portable electronic device, a display unit removable from the main body for displaying a result of the function performed by the main body, and a transmission line for electrically connecting the main body and the display unit allowing the display unit to be separated from the main body without disconnecting the electrical connection between the display unit and the main body.

In one aspect, the portable electronic device further comprises a chamber for storing the transmission line.

Also in accordance with the present invention, there is provided a portable electronic device that comprises a main body for performing a function of the portable electronic device, a display unit for displaying a result of the function performed by the main body, and a transmission line for electrically connecting the main body and the display unit being held at a first position to allow the display unit to engage with the main body, or being held at a second position to allow the display unit to be separated from the main body.

In one aspect, the display unit and the main body are held at substantially the same elevation when the display unit and the main body are engaged to each other.

In another aspect, the main body is held at an elevation different from that of the display unit after the display unit is removed from the main body.

Further in accordance with the present invention, there is provided a method of operating a portable electronic device that comprises providing a transmission line, electrically connecting a main body and a display unit of the portable electronic device with the transmission line, and removing the display unit from the main body by elastically releasing the transmission line.

In one aspect, the method further comprises providing a chamber in the portable electronic device, and storing the transmission line in the chamber.

In another aspect, the method further comprises operating the display unit at a first elevation, and operating the main body at a second elevation different from the first elevation.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate one embodiment of the present invention and together with the description, serves to explain the principles of the invention.

### BRIEF DESCRIPTION OF THE DRAWINGS

Reference will now be made in detail to the present embodiment of the invention, an example of which is illustrated in the accompanying drawings. Wherever possible, the same reference numbers are used throughout the drawings to refer to the same or like parts.

FIG. 1 is a perspective view of a prior art portable electronic device;

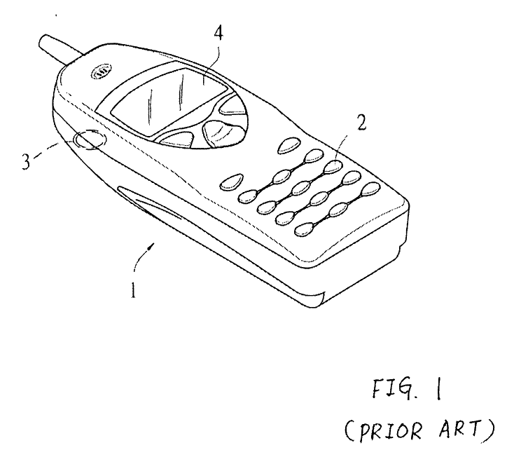

FIG. 2A is a perspective view of a hand-held device in accordance with one embodiment of the present invention;

FIG. 2B is a perspective view of the hand-held device shown in FIG. 2A when a display unit is removed from a main body;

FIG. 2C is a plan view of the hand-held device shown in FIG. 2A;

FIG. 3A is a perspective view of a hand-held device in accordance with another embodiment of the present invention;

FIG. 3B is a perspective view of the hand-held device shown in FIG. 3A when a display unit is removed from a main body; and

FIG. 3C is a plan view of the hand-held device shown in FIG. 3B.

### DETAILED DESCRIPTION OF THE INVENTION

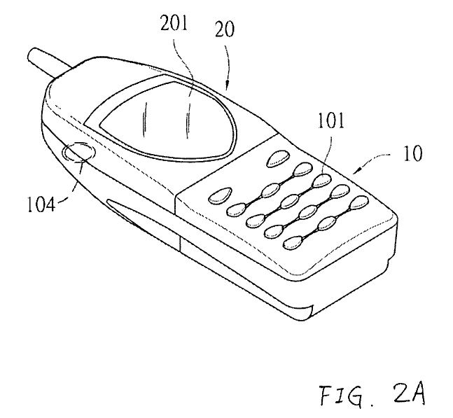

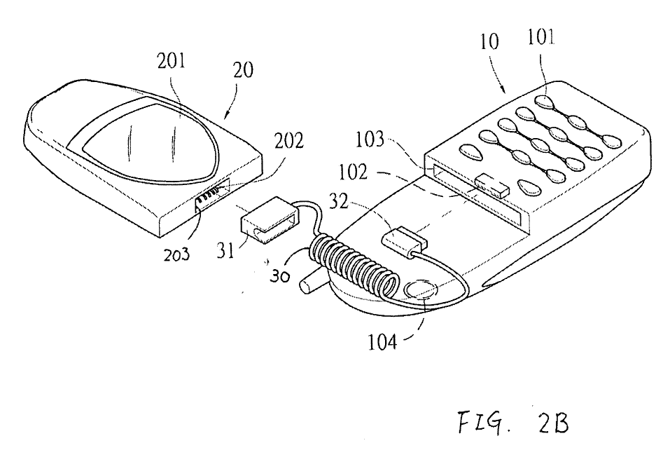

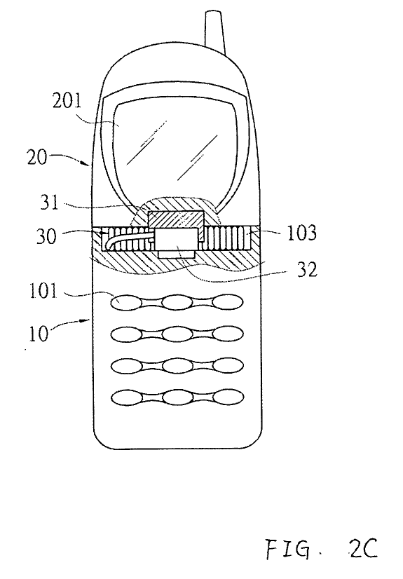

FIG. 2A is a perspective view of a hand-held device in accordance with one embodiment of the present invention. Referring to FIG. 2A, the hand-held device includes a main body 10 and a display unit 20. Main body 10 further includes a control panel 101, for example, a keypad, provided on a front surface (not numbered) thereof, and a camera lens 104 provided on a side surface (not numbered) thereof. Display unit 20 further includes a screen 201 disposed on the front surface of main body 10.

FIG. 2B is a perspective view of the hand-held device shown in FIG. 2A when display unit 20 is separated or removed from main body 10. Referring to FIG. 2B, the hand-held device further includes a transmission line 30 for electrically connecting main body 10 to display unit 20. Transmission line 30 allows display unit 20 to be separated from main body 10 without disconnecting the electrical connection to main body 10. A first connector 31 disposed at one end of transmission line 30 is electrically connected to a connector 202 disposed in a chamber 203 of display unit 20. A second connector 32 disposed at the other end of transmission line 30 is electrically connected to a connector 102 disposed in a chamber 103 of main body 10.

FIG. 2C is a plan view of the hand-held device shown in FIG. 2A. Referring to FIG. 2C, transmission line 30 for transmitting data signals or power signals between main body 10 and display unit 20 is stored in chamber 103.

When the hand-held device is operated in a first mode, as shown in FIG. 2A or FIG. 2C, transmission line 30 is kept in chamber 103. Display unit 20 is not removed from main body 10, and has a first orientation relationship with main body 10. For example, display unit 20 is maintained at substantially the same position or elevation with main body 10 during the first-mode operation.

When the hand-held device is operated in a second mode, as shown in FIG. 2B, transmission line 30 is able to be released from chamber 103. Display unit 20 is removed from main body 10, and has a second orientation relationship with main body 10. For example, display unit 20 is maintained at a position or elevation different from main body 10 during the second-mode operation. When display unit 20 is removed from main body 10, a user is can use camera lens 104 at a first elevation suitable for photography while viewing display screen 201 at a second elevation comfortable to the user. Furthermore, a user can replace a component of the hand-held device, for example, display unit 20, transmission line 30 or main body 10.

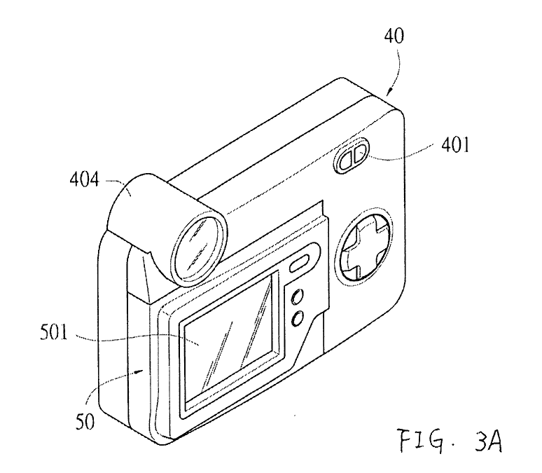

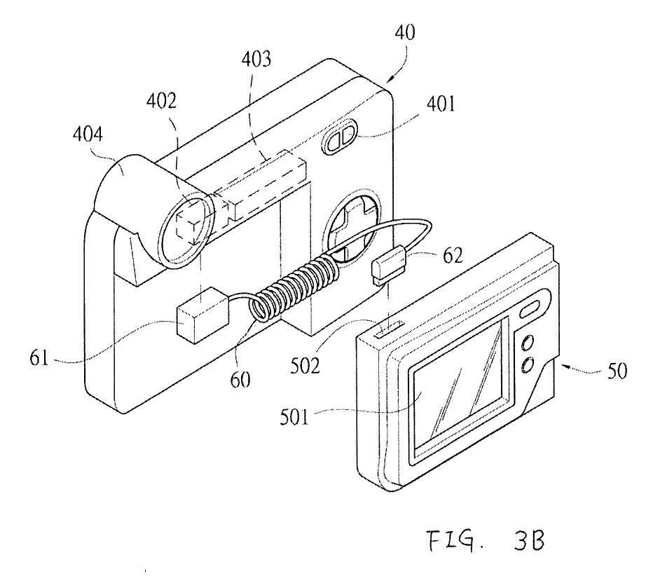

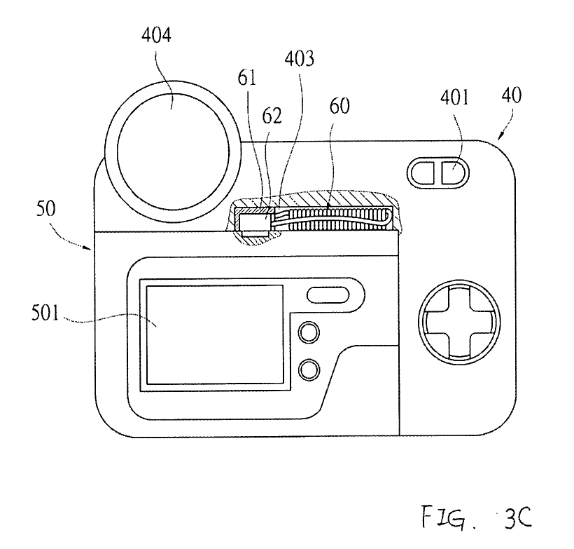

FIG. 3A is a perspective view of a hand-held device in accordance with another embodiment of the present invention. Referring to FIG. 3A, the hand-held device includes a main body 40 and a display unit 50. Main body 40 further includes a control element 401, for example, a shutter button, provided on a front surface (not numbered) thereof, and a camera lens 404 provided on a side surface (not numbered) thereof. Display unit 50 further includes a screen 501 disposed on the front surface of main body 40.

FIG. 3B is a perspective view of the hand-held device shown in FIG. 3A when display unit 50 is removed from main body 40. Referring to FIG. 3B, the hand-held device further includes a transmission line 60 for electrically connecting main body 40 and display unit 50. Transmission line 60 is made of an elastic and conductive material, and allows display unit 50 to be separated from main body 40 without disconnecting the electrical connection to main body 40. A first connector 61 disposed at one end of transmission line 60 is electrically connected to a connector 402 disposed in a chamber 403 of main body 40. A second connector 62 disposed at the other end of transmission line 60 is electrically connected to a connector 502 formed in display unit 50.

FIG. 3C is a plan view of the hand-held device shown in FIG. 3B. Referring to FIG. 3C, transmission line 60 for transmitting data signals or power signals between main body 40 and display unit 50 is stored in chamber 403.

When the hand-held device is operated in a first mode, as shown in FIG. 3A or FIG. 3C, transmission line 60 is kept in chamber 403. Display unit 50 is not removed from main body 40, and has a first orientation relationship with main body 40. For example, display unit 50 is maintained at substantially the same position or elevation with main body 40 during the first-mode operation.

When the hand-held device is operated in a second mode, as shown in FIG. 3B, transmission line 60 is able to be pulled out of chamber 403. Display unit 50 is removed from main body 40, and has a second orientation relationship with main body 40. For example, display unit 50 is maintained at a position or elevation different from main body 40 during the second-mode operation. A user of the hand-held device is thus able to use camera lens 404 at a lower or higher elevation than that of display screen 201.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

1. A portable electronic device, comprising:
a main body for performing a function of the portable electronic device;
a display unit removable from the main body for displaying a result of the function performed by the main body; and
a transmission line for electrically connecting the main body and the display unit allowing the display unit to be separated from the main body without disconnecting the electrical connection between the display unit and the main body.

2. The device of claim 1, further comprising a camera formed in the main body for performing the function.

3. The device of claim 1, further comprising a chamber for storing the transmission line.

4. The device of claim 1, further comprising a connector disposed at one end of the transmission line for electrical connection to the display unit.

5. The device of claim 1, further comprising a connector disposed at one end of the transmission line for electrical connection to the main body.

6. The device of claim 1, wherein the transmission line is kept in a chamber when the display unit is not removed from the main body.

7. The device of claim 1, wherein the display unit is held at an elevation different from that of the main body after the display device is separated from the main body.

8. The device of claim 6, wherein the display unit is engaged with the main body when the transmission line is kept in the chamber.

9. A portable electronic device, comprising:
a main body for performing a function of the portable electronic device;
a display unit for displaying a result of the function performed by the main body; and
a transmission line for electrically connecting the main body and the display unit, the display unit being disposed at a first position to allow the display unit to engage with the main body, or being disposed at a second position to allow the display unit to be separated from the main body.

10. The device of claim 9, further comprising a chamber for storing the transmission line.

11. The device of claim 9, further comprising a connector disposed at one end of the transmission line for electrical connection to the display unit.

12. The device of claim 9, further comprising a connector disposed at one end of the transmission line for electrical connection to the main body.

13. The device of claim 9, wherein the display unit and the main body are held at substantially the same elevation when the display unit and the main body are engaged to each other.

14. The device of claim 9, wherein the main body is held at an elevation different from that of the display unit after the display unit is separated from the main body.

15. A method of operating a portable electronic device, comprising:
providing a transmission line;
electrically connecting a main body and a display unit of the portable electronic device with the transmission line; and
removing the display unit from the main body by elastically releasing the transmission line.

16. The method of claim 15, further comprising:
providing a chamber in the portable electronic device; and
storing the transmission line in the chamber.

17. The method of claim 15, further comprising:
operating the display unit at a first elevation; and
operating the main body at a second elevation different from the first elevation.

18. The method of claim 16, further comprising operating the main body and the display unit at substantially the same elevation.

19. The method of claim 15, further comprising electrically coupling the transmission line to the main body by a connector.

20. The method of claim 15, further comprising electrically coupling the transmission line to the display unit by a connector.
